(19) United States
(12) Patent Application Publication
(10) Pub. No.: US 2009/0298289 A1
(43) Pub. Date: Dec. 3, 2009

(54) Chemical Mechanical Polishing Composition for Copper Comprising Zeolite

(75) Inventors: Eun-Il Jeong, Daejeon (KR); Hyu-Bum Park, Chungcheongnam-do (KR); Seok-Ju Kim, Chungcheongnam-do (KR); Deok-Su Han, Daejeon (KR); Jung-Ryul Ahn, Daejeon (KR); Jong-Kwan Park, Chungcheongnam-do (KR); Kui-Jong Baek, Daejeon (KR)

Correspondence Address: THE WEBB LAW FIRM, P.C., 700 KOPPERS BUILDING, 436 SEVENTH AVENUE, PITTSBURGH, PA, 15219, US

(73) Assignee: TECHNO SEMICHEM CO., LTD., Seongnam-city (KR)

(21) Appl. No.: 12/295,521

(22) PCT Filed: Mar. 29, 2007
(86) PCT No.: PCT/KR07/01536

§ 371 Date: Apr. 14, 2009

(30) Foreign Application Priority Data
Mar. 31, 2006 (KR) 10-2006-0029291

(51) Int. Cl. H01L 21/463; C09K 13/00; H01L 21/465

(52) U.S. Cl. 438/692; 252/79.1; 257/E21.484; 257/E21.485

(57) ABSTRACT

The present invention relates to a novel slurry composition for copper polishing, comprising zeolite which is a porous crystalline material for CMP of copper film in a semiconductor manufacturing process. The slurry composition according to the present invention comprises zeolite, an oxidant and a polish promoting agent and may further comprise a corrosion inhibitor, a surfactant, an aminoalcohol, an antiseptic and a dispersion agent and pH is in a range of 1 to 7. The zeolite slurry according to the present invention has advantages of absorbing and removing metal cation generated in CMP process by using zeolite and having a low level of scratches as the zeolite has micropores therein and thus its hardness is low. The slurry composition using zeolite of the present invention is usable to both first and second step polishing of copper damascene process and particularly useful as the first step polishing slurry for copper.

### TECHNICAL FIELD

The present invention relates to slurry composition for a chemical mechanical polishing (CMP), comprising zeolite which is a porous crystalline material, and more particularly, to slurry composition useful to polish copper film on a semiconductor substrate.

### BACKGROUND ART

Zeolite can be defined as a crystalline material in which nanopores having a predetermined size are regularly arranged. The zeolite is divided into aluminosilicates, aluminophosphates (AlPO₄), silicoaluminophosphates (SAPO), metal aluminophosphates (MeAPO) and metallosilicates according to its composition.

35 kinds of the zeolites, and more than 130 kinds if adding the zeolite which is artificially synthesized and of which structure is known, are currently known by efforts of many mineralogists since it has been firstly discovered and named at 1756 by the Swedish mineralogist Cronsted.

Composition of aluminosilicate type zeolite is expressed by the following formula:

M_{2/n}O.xAl₂O₃.ySiO₂.zH₂O

wherein M represents cation having an atomic value of n, z represents a molecular number of crystalline water, and y/x which is a ratio of y to x varies as a crystalline structure but has generally a value of 1 to 100.

Zeolite has micropores, in which a size of an interior space is 5 to 20 and a size of an inlet is 3 to 13 whereby a size of a compound incorporable therein is defined. In addition, the zeolite has a void volume of 15 to 50%, a very large surface area, i.e. a surface area of over 200 m²/g and a property that hardness and density are low as Mohr hardness is 2 to 5 and density is 2 to 3 g/cm³.

Water is generally absorbed in an interior of the micropore which exists within the zeolite crystal and, by heating the zeolite crystal, the water molecules in the interior of the micropores are easily goes out to atmosphere and thus the interior of the micropores come to be wholly emptied.

Due to the physical properties of the zeolite as above described, the zeolite has various usages in various chemical processes such as a separation process and a refinement process as having unique absorption property, catalytic activity and ion exchange capacity etc. and is widely used as a substitute of a phosphate detergent builder which causes water pollution as having high cation exchange capacity and ecological stability.

The zeolites includes much various kinds such as A type, X and Y type, and ZSM-5 type etc. which are named according to its structure and naming of an inventor, and synthetic zeolites are generally synthesized in a size of 1 to 5 μm and there are zeolite A, ZSM-5, zeolite-X or Y and zeolite-L as the representative zeolites. In the zeolite A, an inlet size is 3 to 5 Å according to exchanged cation and there is a large cavity having a diameter of approximate 11 Å and called as a supercage or an α-cage therein. In the zeolite called according to a ratio of silicon to aluminum (Si/Al) as X (Si/Al=1 to 1.5) or Y (Si/Al=1.6 to 3), the inlet size is 7.4 Å and there is a supercage having a diameter of approximate 13 Å therein. Such zeolite may be called as cage type zeolite. On the contrary, there is a channel type zeolite such as ZSM-5 and zeolite-L. A channel having a size of 5.5×5.1 Å and a channel having a size of 5.3×5.6 Å lie perpendicular to each other in case of ZSM-5 and a channel having a size of 5.3×5.6 Å runs in one direction in case of zeolite-L. Water molecules as well as large cations are free to move in and out of an interior of the nanopores.

The zeolite having the properties as above described may be used as a detergent builder by using a property of absorbing Ca²⁺ and Mg²⁺ within water to soften the water or may be used as an absorbent since it is capable of incorporating molecules or water into the micropores. In addition, the zeolite is used to remove toxic gas or toxic compound as used as a cigarette filter or a water treating agent for purifying polluted water, and particularly used a lot as a catalyst having size selectivity and an orientation selectivity in a petrochemical industry and there is also known zeolite catalyst containing Cu ion. Besides, the zeolite is used as a molecular sieve performing a selective absorption using micropores having a predetermined size, a synthetic resin additive (a light weight filler) and light weight construction materials, etc.

The present inventors have accomplished this invention by finding that the zeolite has superior polishing properties in case of being applied to polish a semiconductor substrate including metals since the zeolite has interior micropores incorporable of compounds and arranged regularly and thus, if the zeolite is used in CMP, the zeolite can incorporate useful compound before CMP and can absorb and remove generated metallic cations after CMP, and it is possible to restrain generation of scratches during—polishing process as having low hardness and density compared to the conventional inorganic particles.

A polishing composition comprising the zeolite could have superior polishing properties of restraining generation of scratches in case of being applied to polishing of copper having a low hardness and absorbing metallic cations generated after polishing into interior micropores of the zeolite thereby improving removal rate.

### DISCLOSURE OF INVENTION

### Technical Problem

An object of the present invention is to provide a polishing composition for a semiconductor substrate, comprising zeolite which is a porous crystalline material.

In addition, another object of the present invention is to provide a polishing composition, comprising zeolite which is a porous crystalline material and thus restraining generation of scratches in case of polishing metal component having low hardness such as copper and having high removal rate of copper film.

### Technical Solution

The present invention relates to slurry for CMP of copper on a semiconductor substrate comprising zeolite and the polishing slurry composition comprises the zeolite, an oxidant and a polish promoting agent.

The polishing composition has the advantages of restraining generation of scratches and having high removal rate of a metal film particularly in case of polishing metal component having low hardness such as copper.

In addition, the polishing composition according to the present invention may further comprise a corrosion inhibitor, a surfactant, an aminoalcohol, an antiseptic and a dispersion agent and may further include a pH adjuster in order to maintain pH to 1 to 7.

In the polishing composition according to the present invention, the zeolite has an advantage of the aspect of having micropores exposed on its surface, compared to conventional inorganic particles having no micropore. In addition, there is an advantage of reducing scratches since the zeolite has an empty space therein and thus is easily crushable by physical force. In addition, there are advantages that removal rate can be improved as the zeolite is capable of absorbing metallic ions such as Cu²⁺ which is generated when polishing a metallic film and environment pollution can be prevented as the polishing composition itself absorbs and thus removes copper ions. In addition, there is another advantage of selective action on the film to be polished by incorporating additives in micropores of the zeolite when manufacturing the polishing composition so that when the zeolite particles are crushed by applied physical force during polishing the incorporated material is discharged and contacted with the metal film to be polished. For example, selected compounds capable of increasing removal rate or restraining scratches (or defects) may be incorporated to act on the surface of the film to be polished when performing CMP.

The zeolite is conventionally manufactured in composition comprising Na⁺ ion, the Na⁺ ion however may contaminate a semiconductor substrate and thus cause defects of semiconductor. The polishing composition according to the present invention preferably comprises zeolite without Na⁺ ion and more preferably comprises zeolite exchanged with K⁺ ion, NH₄⁺ ion or H⁺ ion. A mole ratio of SiO₂/Al₂O₃ of zeolite is conventionally greater than 1, but it is preferable that the mole ratio of SiO₂/Al₂O₃ is greater than 10. This is because a content of alkali metals or alkaline earth metals is increased if the mole ratio is low, whereby increases a possibility of causing contamination of the alkali metals or the alkaline earth metals.

It is preferable that zeolite comprised in the polishing composition according to the present invention has a particle diameter of less than 1000 nm, a surface area of more than 200 m²/g, a void volume of greater than 15 volume % and a micropore diameter of 3 to 25 . The particle diameter is preferably in a range of 10 to 1000 nm, more preferably in a range of 50 to 600 nm if the particle diameter exceeds 1000 nm it is disadvantageous since scratches may be generated due to macroparticles and if the particle diameter is less than 10 nm it is not preferable that there are problems of difficulty in a manufacture and decrease in a removal rate. The zeolite may be used after pulverization to the above mentioned particle diameter useful to the polishing composition. Crystallinity of the zeolite may be decreased or lost in the pulverization process. The present invention however comprises even the pulverized material of the zeolite. If the surface area is greater than 200 m²/g and the void volume is greater than 15 volume %, it is advantageous since properties of absorbing metal ions and incorporating compounds become superior with an increase of the values, however actually possible range of the surface area is 200 to 2000 m²/g and that of the void volume is 15 to 50 volume %. The surface area can be increased by adjusting pulverization or manufacturing condition. In addition, performance of absorbing metal ion and compound is insignificant in case that the diameter of the micropore is less than 3 and there are problems that a structure becomes unstable and durability is weak in case that the diameter of the micropore exceeds 25.

The zeolite is conventionally classified into A type, X type, Y type, beta type, L type and ZSM-5 type etc. and the A type is classified into 3A, 4A and 5A types according to size of micropore though it is not necessary to limit the kind of the zeolite as any type of zeolite can be used if satisfies the above physical properties, it was more preferable to use ZSM-5 since polishing property is superior.

A content of the zeolite comprised in the polishing composition according to the present invention is preferably 0.01 to 20 wt %, more preferably 0.1 to 10 wt % and the most preferably 0.2 to 5 wt % based on total weight of slurry. Removal rate is low and absorption amount of metal ions is small if the content is less than 0.01 wt %. Dispersion stability becomes worse and generation frequency of scratches is high if the content exceeds 20 wt %.

The polishing slurry composition may comprise 0.01 to 20 wt % of zeolite, 0.01 to 15 wt % of an oxidant and 0.01 to 5 wt % of a polish promoting agent, and its pH is preferably 1 to 7.

The oxidant acts to oxidize a surface of a metal film and comprises a compound having at least one peroxy radical, a compound comprising an atom which exists in its highest oxidation state or a mixture thereof. As specific examples of the compound having at least one peroxy radical, there are hydrogen peroxide products such as hydrogen peroxide, urea hydrogen peroxide and percarbonates, organic peroxides such as benzoyl peroxide, peracetic acid and di-t-butyl peroxide, monopersulfates, dipersulfates, sodium peroxide and a mixture thereof. As specific examples of the compound comprising an atom which exist in its highest oxidation state, there are periodates, perboric acid, perborates, permanganates and the like. In addition, it is possible to use non per compounds. As specific examples of the usable non per compounds, there are bromates, chromates, iodates, iodic acid salts, iodic acid and cerium (IV) compound such cerium ammonium nitrate, and it is also possible to use a compounds such as iron (III) nitrate. It is the most preferable to use the hydrogen peroxide as the oxidant.

A content of the oxidant is preferably 0.01 to 15 wt % of the total polishing composition, more preferably 0.1 to 10 wt %. There are problems that an oxidizing power is small and thus removal rate is low if the content of the oxidant is less than 0.01 wt % and that corrosiveness may increase if the content of the oxidant exceeds 15 wt %.

The polish promoting agent acts to increase removal rate of metal film and, as the polish promoting agent, a material selected from organic acid, amino acid, chelating agent, organophosphate type complexing agent, polymeric organic acid or salt thereof may be used alone or in an admixture thereof. It is preferable that the salt is not sodium salt and this is because the Na ion may cause defect on the semiconductor substrate. As the organic acid, for example, citric acid, adipic acid, succinic acid, oxalic acid, gluconic acid, tartaric acid, malic acid, mercaptosuccinic acid (MSA), benzenetetracarboxylic acid (BTTCA) and the like may be used. As the amino acid, for example, glutamic acid, alanine, glycine, aspartic acid and the like may be used. The chelating agent comprises both nitrogen atom and carboxylic radical and as the chelating agent, for example, ethylenediaminetetraacetic acid (EDTA), nitrilotriacetic acid (NTA), iminodiacetic acid (IDA), quinolinic acid (QNA) and the like may be used. As the organophosphate type complexing agent, for example, nitrilotris(methylene)triphosphonic acid (NTPA) may be included. As the polymeric organic acid, for example, polyacrylic acid (PAA) may be used. The polish promoting agent selected from the citric acid, the glycine, NTPA, BTTCA, the tartaric acid, QNA, the malic acid or salt thereof is more preferable as the removal rate is high.

A content of the polish promoting agent is 0.01 to 5 wt % of total polishing composition, more preferably 0.01 to 3 wt %, most preferably 0.03 to 1.0 wt %. Since the polishing composition according to the present invention comprises zeolite and the zeolite has a very large surface area and interior micropores and thus has a property of absorbing metal ions, there is an advantage of exhibiting superior polishing property even if using the polish promoting agent in much lower content than that of conventional polishing composition. It is disadvantageous that corrosiveness is increased if the content of the polish promoting agent exceeds 5 wt % and that the removal rate may be decreased if the content of the polish promoting agent is less than 0.01 wt %.

A mechanism of polishing a metal film, particularly a copper film, using the polishing composition according to the present invention varies as a range of pH. It is necessary to select a proper pH range because contribution of copper dissolution is increased when pH becomes lower and otherwise in neutral pH a mechanism that the copper film is oxidized to copper oxide film, which is removed mechanically, is more important. Further, a polishing property is influenced complexly by contents of oxidant, polish promoting agent and corrosion inhibitor even in the same pH.A proper pH range of the polishing composition according to the present invention is 1 to 7, more preferably 2 to 5. For adjustment of pH, as a basic material, KOH, ammonia, tetramethylammonium hydroxide and the like may be used alone or in an admixture thereof and, as acidic material, inorganic acid such as nitric acid, phosphoric acid, sulfuric acid, hydrochloric acid and the like may be properly added. It is not suitable as removal rate is decreased if the pH is higher than the range and it is disadvantageous as corrosiveness is increased if the pH is lower than the range.

The polishing composition according to the present invention may be manufactured by further adding a corrosion inhibitor, an aminoalcohol, a surfactant, an antiseptic and a dispersion agent.

The corrosion inhibitor is selected from a group consisting of benzotriazole, 5-aminotetrazole, 1-alkyl-5-aminotetrazole, 5-hydroxy-tetrazole, 1-alkyl-5-hydroxy-tetrazole, tetrazole-5-thiol, imidazole and a mixture thereof. The benzotriazole and the 5-aminotetrazole are more preferable viewed in points of a corrosion inhibiting performance and a commercial usability. The content of the corrosion inhibitor is preferably 0.0001 to 1 wt % of total polishing composition, and more preferably 0.001 to 1 wt %. There is a disadvantage that a removal rate is decreased in case that the content exceeds 1 wt % and it may be occurred that an etching rate of a metal film is increased in case that the content is less than 0.0001 wt %.

The aminoalcohol is added in a content of 0.001 to 2 wt %, more preferably 0.01 to 0.5 wt % for preventing absorption of zeolite particles and increasing dispersion stability of the polishing composition. Dispersibility may be rather lowered and a problem of decreasing removal rate is occurred in case that the content exceeds 2 wt %. It is not preferable as a performance of preventing particle absorption is low and the dispersion stability is lowered in case that the content is less than 0.001 wt %. The aminoalcohol may be selected from a group consisting of 2-amino-2-methyl-1-propanol (AMP), 3-amino-1-propanol, 2-amino-1-propanol, 1-amino-2-propanol, 1-amino-pentanol, 2-(2-aminoethylamino)ethanol, 2-dimethylamino-2-methyl-1-propanol, N,N-diethylethanolamine, monoethanolamine, diethanolamine, triethanolamine and a mixture thereof and it was more preferable to use 2-amino-2-methyl-1-propanol, monoethanolamine or a mixture thereof as an effect is superior.

The polishing composition according to the present invention may further comprise a surfactant in a content of 0.0001 to 0.01 wt % of total weight of the polishing composition. An effect of surface activation is not exhibited if the usage content is too low and bubbles may be generated if the usage content is too high.

As the dispersion agent, for example, polyacrylic acid type, phosphoric acid type or sulfonic acid type dispersion agent may be used. It is used preferably a content of 0.001 to 0.5 wt % of total weight of the polishing composition, and more preferably 0.003 to 0.2 wt %. A function as dispersion agent is weak if the concentration is too low and dispersibility may be rather damaged if the concentration is too high.

The polishing composition according to the present invention may be further added with antiseptic for giving a function of inhibiting decay of organic materials. The content is preferably 0.001 to 0.5 wt % and more preferably 0.01 to 0.2 wt %. An effect of decay inhibition is insignificant if the content is too low and it is disadvantageous as polishing property may be influenced if the content is too high.

A more preferable polishing composition for metal polishing according to the present invention comprises 0.1 to 10 wt % of the zeolite having a particle diameter of 50 to 600 nm and exchanged with NH₄⁺, K⁺ or H⁺ ion, 0.1 to 10 wt % of hydrogen peroxide and 0.03 to 1 wt % of polish promoting agent selected from citric acid, glycine, nitrilotris(methylene)triphosphonic acid (NTPA), benzenetetracarboxylic acid (BTTCA), tartaric acid, quinolinic acid (QNA), malic acid or salt thereof, and has pH of 2 to 5. In addition, the polishing composition may further comprise 0.01 to 0.5 wt % of aminoalcohol and 0.001 to 0.1 wt % of corrosion inhibitor if necessary.

In addition, the present invention is further added with organic solvent having a good miscibility with water for helping dissolution of polish promoting agent. The organic solvent comprises alcohols, for example, ethanol, methanol and propanol. A content of the organic solvent is 0.1 to 10 wt % of total polishing composition.

### BEST MODE FOR CARRYING OUT THE INVENTION

Hereinafter, the embodiments of the present invention will be described in detail. However, it will be appreciated that those skilled in the art, on consideration of this disclosure, may make modifications and improvements within the spirit and scope of the present invention.

### EXAMPLE

As zeolite used in the present invention was used ZSM-5 type, Y type and 4A type. The ZSM-5 type has SiO₂/Al₂O₃ratio of 30 to 32 and is exchanged with NH₄⁺ ion the Y type has SiO₂/Al₂O₃ ratio of 30 to 80 and is exchanged with H⁺ ion and in the 4A type, Na⁺ ion is not exchanged. These were pulverized and dispersed by a media agitating mill using zirconia balls and particle size was measured by Horiba LA 910.

As a wafer used in polishing, a copper wafer in which TaN is deposited on a silicon substrate to a thickness of 250 Å and then Cu is deposited using a PVD method to a thickness of 10000 Å was used a copper polishing test was carried out using Poli 500CE of G&P Technology Co., Ltd. as a polishing machine and a Rodel IC1400 as a polishing pad a polishing condition was as follows: Table/Head speed=30/30 rpm, polishing pressure=100 g/cm² and flow rate of slurry=200 ml/min. Thickness of the copper film was measured by Four Point Probe of Changmin Technology Co., Ltd. and thickness of PETEOS film was measured by a thickness measurement system of Kmac Co., Ltd.

In the present embodiments, % means wt % unless another definition is clearly provided, and KOH and HNO₃ was used as pH adjuster.

### Example 1

Polishing compositions were prepared as shown in Table 1 using zeolite ZSM-5(NH₄⁺) which is exchanged with NH₄⁺ ion and citric acid as a polish promoting agent. In Table 1 below, BTA represents benzotriazole. A slurry using 4 wt % of fumed silica having surface area of 150 m²/g was prepared and used under the same condition for comparison.

TABLE 1

| | Zeolite | | | | | | | |
|---|---|---|---|---|---|---|---|---|
| | | Average | | Polish | | | Cu | Cu surface |
| | | particle | | promoting | corrosion | | Removal | condition |
| No. of | | diameter | H₂O₂ | agent | Inhibitor and | | rate | after |
| Experiment | wt % | (nm) | wt % | wt % | wt % | pH | (Å/min) | polishing |
| 1-1 | 4 | 150 | 4 | 0.5 | | 4 | 7238 | ⊚ |
| 1-2 | 4 | 150 | 4 | 0.5 | | 5 | 5226 | ⊚ |
| 1-3 | 4 | 351 | 4 | 0.5 | | 4 | 5372 | ⊚ |
| 1-4 | 0.5 | 544 | 4 | 0.5 | | 5 | 4079 | ⊚ |
| 1-5 | 4 | 544 | 4 | 0.5 | | 5 | 5092 | ⊚ |
| 1-6 | 2 | 544 | 4 | 0.5 | BTA 0.01% | 5 | 4015 | ⊚ |
| Comparative | 4 wt | | 4% | 0.5 | | 4 | 3262 | Δ |
| Example | % of | | | | | | | |
| | fumed | | | | | | | |
| | silica | | | | | | | |

Condition of polished Cu surface ⊚ good, Δ fair, X: poor

As shown in Table 1, the polishing compositions comprising zeolite, hydrogen peroxide and citric acid have high removal rate even at low pressure and show higher copper removal rate compared with the fumed silica and further surface condition of polished copper is good.

### Example 2

Polishing property according to pH variation ZSM-5(NH₄⁺) zeolite having an average particle diameter of 351 nm was used, 4% of hydrogen peroxide and 0.5% of citric acid were comprised and KOH and HNO₃ were used for adjusting pH.

TABLE 2

| No. of | | Cu Removal rate | Cu surface condition |
|---|---|---|---|
| Experiment | pH | (Å/min) | after polishing |
| 2-1 | 3 | 5802 | ⊚ |

As a result of evaluating in a range of pH 3 to pH 5, high removal rates were obtained.

### Example 3

Polishing property according to a content of the zeolite ZSM-5(NH₄⁺) zeolite having an average particle diameter of 544 nm was used and a content of the zeolite was varied as Table 3. A content of hydrogen peroxide was 4%, a content of citric acid was 0.5% and pH was adjusted to 5.

TABLE 3

| No. of | Concentration of | Cu Removal rate | Cu surface condition |
|---|---|---|---|
| Experiment | zeolitewt % | (Å/min) | after polishing |
| 3-1 | 0.5 | 4079 | ⊚ |

As shown in Table 3, the removal rate was slightly increased with increasing concentration of the zeolite, and a sufficient removal rate was provided even if using a small content of 0.5 wt %.

### Example 4

Polishing property according to type and content of the polish promoting agent ZSM-5(NH₄⁺) zeolite was used. Also Y(30/H⁺) type and Y(80/H⁺) type which are Y type zeolites having SiO₂/Al₂O₃ ratio of 30 and 80 respectively and exchanged with H⁺ ion and 4A type zeolites were used. Kinds and contents of the polish promoting agent are shown in Table 4 below. pH, wt % of hydrogen peroxide, and additional additives and their wt % are also shown.

TABLE 4

| | Zeolite | | | | | | | | |
|---|---|---|---|---|---|---|---|---|---|
| | | | Average | | Polish | | | Cu | Cu surface |
| | | | particle | | promoting | Additional | | Removal | condition |
| No. of | | | diameter | H₂O₂ | agent and | additive and | | rate | after |
| experiment | Kind | wt % | (nm) | Wt % | wt % | wt % | p | (Å/min) | polishing |
| 4-1 | ZSM-5(NH₄⁺) | 4 | 351 | 4 | Tartaric acid | | 4 | 3798 | ⊚ |
| | | | | | 0.5% | | | | |
| 4-2 | ZSM-5(NH₄⁺) | 2 | 544 | 4 | Succinic acid | | 5 | 2512 | ⊚ |
| | | | | | 0.5% | | | | |
| 4-3 | ZSM-5(NH₄⁺) | 2 | 544 | 4 | Oxalic acid | | 5 | 2014 | ⊚ |
| | | | | | 0.5% | | | | |
| 4-4 | ZSM-5(NH₄⁺) | 2 | 544 | 4 | Glycine | | 5 | 4638 | Δ |
| | | | | | 0.5% | | | | |
| 4-5 | 4A | 2 | 411 | 4 | Adipic acid | | 5 | 2330 | ⊚ |
| | | | | | 0.5% | | | | |
| 4-6 | ZSM-5(NH₄⁺) | 2 | 324 | 4 | Aspartic acid | | 5 | 2193 | ⊚ |
| | | | | | 0.5% | | | | |
| 4-7 | ZSM-5(NH₄⁺) | 4 | 150 | 4 | Cirtic acid | | 4 | 2459 | ⊚ |
| | | | | | 0.08% | | | | |
| 4-8 | ZSM-5(NH₄⁺) | 4 | 351 | 4 | Cirtic acid | | 4 | 4086 | ⊚ |
| | | | | | 2% | | | | |
| 4-9 | ZSM-5(NH₄⁺) | 2 | 324 | 4 | EDTA 0.5% | | 5 | 1862 | Δ |
| 4-10 | ZSM-5(NH₄⁺) | 2 | 324 | 4 | IDA 0.5% | | 5 | 2667 | ⊚ |
| 4-11 | ZSM-5(NH₄⁺) | 2 | 324 | 4 | NTPA 0.5% | | 5 | 7581 | |
| 4-12 | ZSM-5(NH₄⁺) | 2 | 324 | 4 | PAA 0.5% | | 5 | 1424 | |
| 4-13 | ZSM-5(NH₄⁺) | 2 | 324 | 4 | Alanine | | 5 | 2532 | |
| | | | | | 0.5% | | | | |
| 4-14 | ZSM-5(NH₄⁺) | 2 | 324 | 4 | NTA 0.5% | | 5 | 1226 | |
| 4-15 | ZSM-5(NH₄⁺) | 2 | 324 | 4 | Cirtic acid | | 5 | 3955 | |
| | | | | | 0.08% | | | | |
| | | | | | Gluconic acid | | | | |
| | | | | | 0.5% | | | | |
| 4-16 | Y(30/H⁺) | 4 | 218 | 4 | NTPA | | 3.9 | 3863 | |
| | | | | | 0.43% | | | | |
| 4-17 | Y(80/H⁺) | 4 | 270 | 4 | NTPA | | 3.9 | 5750 | |
| | | | | | 0.43% | | | | |
| 4-18 | ZSM-5(NH₄⁺) | 2 | 146 | 4 | Malic acid | BTA 0.02% | 5 | 3041 | |
| | | | | | 0.18% | | | | |
| 4-19 | ZSM-5(NH₄⁺) | 4 | 146 | 4 | QNA 0.25% | BTA 0.01% | 4 | 3662 | |

As shown in Table 4, in polishing compositions using zeolite, various polish promoting agents such as an organic acid, an amino acid, a chelating agent, an organophosphate type complexing agent (NTPA), a polymeric organic acid, for example, polyacrylic acid (PAA) and the like and mixture thereof exhibited copper removal rates sufficient to be used in copper polishing composition. Use of citric acid, glycine, NTPA, BTTCA, tartaric acid, malic acid, QNA and mercaptosuccinic acid (MSA) as the polish promoting agents exhibited higher removal rates.

### Example 5

Polishing compositions, comprising 2 wt % of ZSM-5(NH₄⁺) zeolite having an average particle diameter of 544 nm and 4 wt % of hydrogen peroxide, were prepared with varying pH and composition of the polish promoting agent as Table 5 below. Removal rates of TaN, PETEOS, and copper film are measured.

TABLE 5

| | | | | | Cu surface |
|---|---|---|---|---|---|
| No. of | | | | | condition |
| Experi- | Polish promoting | Removal rate (/min) | | | after |
| ment | agent, composition | Cu | TaN | PETEOS | polishing |
| 5-1 | EDTA 0.5%, pH = 5 | 1862 | 73 | 59 | |
| 5-2 | NTPA 0.5%, pH = 5 | 7581 | 477 | 61 | |
| 5-3 | Glycine 0.5%, BTA | 5406 | 513 | 61 | |
| | 0.04%, pH = 3 | | | | |

As shown in Table 5, it will be appreciated that the removal rate for copper is high and the removal rates for TaN and PETEOS are low and it is possible to selectively polish the copper film as removal rate ratio of Cu/TaN or Cu/PETEOS is more than 10. Those are suitable as first step slurry for copper damascene process as those have high copper removal rate for copper and high copper selectivity.

### Example 5

### Polishing Property According to Content of Hydrogen Peroxide

Compositions of pH=4, including 4 wt % of ZSM-5(NH₄⁺) having an average particle diameter of 150 nm, 0.5% of BTTCA as polish promoting agent, 0.001% of BTA, and 2% of ethanol for helping a dissolution of BTTCA, were prepared and, at that time, the hydrogen peroxide was varied in concentration as Table 6.

TABLE 6

| No. of | Hydrogen | Cu Removal rate | Cu surface condition |
|---|---|---|---|
| Experiment | peroxidewt % | (/min) | after polishing |
| 6-1 | 2 | 5942 | |

Sufficient copper removal rates were exhibited at every hydrogen peroxide concentration of 2 to 8 and the polished copper surfaces also are very good without scratches or corrosion.

### Example 7

### Cu²⁺ Ion Absorption Ability of Zeolite

Copper nitrate solutions were prepared, and then 2 wt % s of NH₄⁺-exchanged ZSM-5 zeolite [ZSM-5(NH₄⁺)], fumed silicas having surface areas of 200 m²/g and 150 m²/g, and fumed alumina having a surface area of 100 m²/g respectively were added into the solutions and then digested. Then the particles were filtered off and concentrations of Cu²⁺ ion in the aqueous solutions were measured. PH of the each aqueous solution was adjusted to 5. A concentration of Cu²⁺ ion in an aqueous solution, which was not digested with the particles and diluted at the same ratio, was measured to be 540 ppm.

TABLE 7

| | | | Concentration of |
|---|---|---|---|
| No. of | | Particle size | remained Cu²⁺ in |
| Experiment | Kind of particle | (nm) | solution (ppm) |
| 7-1 | Zeolite ZSM-5(NH₄⁺) | 271 | 0.04 |

The zeolite absorbed and removed almost all Cu²⁺ ions in the aqueous solution and thus the copper ion was not remained in the aqueous solution, and this shows that Cu²⁺ ion absorption and removal ability of zeolite is very superior. On the contrary, fumed silica and fumed alumina could not remove the Cu²⁺ ion. It is known that copper ion is generated in a copper CMP process and, if a concentration of the generated copper ion is lowered by the zeolite, the polished copper (or copper oxide) can be rapidly dissolved thereby increasing the removal rate. In other words, the zeolite can contribute an improvement in removal rate by helping a function of the polish promoting agent. In addition, the copper ion generated in the polishing process must be removed from waste solution after polishing as it is a material which is toxic to human body and generates environment pollution and, in case of polishing composition comprising zeolite, it is very advantageous as the copper ion in waste water can be easily removed since the zeolite which is a component collects the copper ion.

### INDUSTRIAL APPLICABILITY

As described above, the present invention relates to a copper film polishing composition comprising zeolite which is porous crystalline material and has very large surface area and is capable of incorporating or absorbing a compound having a suitable size.

The polishing composition according to the present invention comprises zeolite, oxidant and polish promoting agent and is suitable for first step polishing in copper damascene process as it maintains high removal rate for copper film while the removal rates for other films are low and has another advantages of having a low scratch level and absorbing copper ion generated after polishing thereby not generating an environmental problem.

1. Slurry composition for copper polishing, comprising 0.01 to 20 wt % of zeolite.

2. The slurry composition for copper polishing as set forth in claim 1, wherein the zeolite has a particle size of less than 1000 nm and a surface area of greater than 200 m²/g.

3. The slurry composition for copper polishing as set forth in claim 2, wherein the zeolite has a SiO₂/Al₂O₃ mole ratio of greater than 10 and a micropore diameter of 3 to 25 and exchanged with ammonium ion, potassium ion or hydrogen ion.

4. The slurry composition for copper polishing as set forth in claim 3, wherein the zeolite is a ZSM-5 type.

5. The slurry composition for copper polishing as set forth in claim 1, further comprising oxidant and polish promoting agent.

6. The slurry composition for copper polishing as set forth in claim 5, having pH of 1 to 7.

7. The slurry composition for copper polishing as set forth in claim 5, wherein the oxidant is 0.01 to 15 wt % of hydrogen peroxide based on total weight of the slurry.

8. The slurry composition for copper polishing as set forth in claim 5, comprising, as the polish promoting agent, 0.01 to 5 wt %, based on total weight of the slurry, of at least one selected from organic acid, amino acid, chelating agent, organophosphate type complexing agent, polymeric organic acid or salt thereof.

9. The slurry composition for copper polishing as set forth in claim 8, comprising, as the polish promoting agent, 0.01 to 3 wt %, based on total weight of the slurry, of at least one selected from organic acid selected from citric acid, adipic acid, succinic acid, oxalic acid, gluconic acid, malic acid, tartaric acid, mercaptosuccinic acid or benzenetetracarboxylic acid; amino acid selected from glutamic acid, alanine, glycine or aspartic acid chelating agent selected from ethylenediaminetetraacetic acid, nitrilotriacetic acid, iminodiacetic acid or quinolinic acid; nitrilotris(methylene)triphosphonic acid which is an organophosphate type complexing agent; polyacrylic acid which is polymeric organic acid; or salt thereof.

10. The slurry composition for copper polishing as set forth in claim 1, further comprising at least one of a corrosion inhibitor, aminoalcohol, surfactant, antiseptic and dispersion agent.

11. The slurry composition for copper polishing as set forth in claim 10, which comprises 0.0001 to 1 wt % of the corrosion inhibitor selected from the group consisting of benzotriazole, 5-aminotetrazole, 1-alkyl-5-aminotetrazole, 5-hydroxy-tetrazole, 1-alkyl-5-hydroxy-tetrazole, tetrazole-5-thiol, imidazole and a mixture thereof and 0.001 to 2 wt % of aminoalcohol selected from a group consisting of 2-amino-2-methyl-1-propanol, 3-amino-1-propanol, 2-amino-1-propanol, 1-amino-2-propanol, 1-amino-pentanol, 2-(2-aminoethylamino)ethanol, 2-dimethylamino-2-methyl-1-propanol, N,N-diethylethanolamine, monoethanolamine, diethanolamine, triethanolamine and mixtures thereof.

12. The slurry composition for copper polishing as set forth in claim 11, which comprises 0.1 to 10 wt % of the zeolite having an average particle diameter of 50 to 600 nm and a surface area of greater than 200 m²/g and exchanged with ammonium ion, potassium ion or hydrogen ion, 0.1 to 10 wt % of hydrogen peroxide and 0.01 to 3 wt % of polish promoting agent selected from citric acid, glycine, nitrilotris(methylene)triphosphonic acid, benzenetetracarboxylic acid, quinolinic acid, mercaptosuccinic acid or salt thereof, 0.01 to 0.5 wt % of 2-amino-2-methyl-1-propanol, monoethanolamine or a mixture thereof, and 0.001 to 0.1 wt % of benzotriazole, 5-aminotetrazole or a mixture thereof, and has pH of 2 to 5.

13. A method for manufacturing a semiconductor device, proceeding with a first CMP process of copper damascene process using the slurry composition for copper polishing as set forth in claim 1.
